(19) United States
(12) Patent Application Publication
(10) Pub. No.: US 2025/0324869 A1
(43) Pub. Date: Oct. 16, 2025

(54) DISPLAY DEVICE

(71) Applicant: Sharp Display Technology Corporation, Kameyama City, Mie (JP)

(72) Inventor: Tamotsu SAKAI, Kameyama City (JP)

(21) Appl. No.: 18/855,780

(22) PCT Filed: Jun. 8, 2022
(86) PCT No.: PCT/JP2022/023176

§ 371 Date: Oct. 10, 2024

(51) Int. Cl. H10K 59/131; G09G 3/3233; H10K 59/121

(52) U.S. Cl. CPC H10K 59/131; G09G 3/3233; H10K 59/1213; G09G 2300/0426; G09G 2300/0819; G09G 2300/0852; G09G 2300/0861

(57) ABSTRACT

An initialization transistor and a threshold voltage compensation transistor are connected via a first wiring line, a gate electrode of a drive transistor is connected to the first wiring line via a second wiring line, and in each subpixel, a first scanning signal line of a gate electrode of a write control transistor, a second scanning signal line of a gate electrode of the threshold voltage compensation transistor, and the second scanning signal line of a gate electrode of the initialization transistor are provided so as to extend parallel to each other, a third wiring line is connected to the second wiring line, and the first wiring line is provided so as to cover the third wiring line above the first scanning signal line.

### TECHNICAL FIELD

The disclosure relates to a display device.

### BACKGROUND ART

In recent years, as a display device replacing a liquid crystal display device, a self-luminous organic electroluminescence (hereinafter also referred to as “EL”) display device using an organic EL element has attracted attention. In the organic EL display device, a plurality of thin film transistors (hereinafter also referred to as “TFTs”) are provided for each subpixel being the smallest unit of an image. Well-known examples of a semiconductor layer constituting the TFT include a semiconductor layer made of polysilicon having high mobility, and a semiconductor layer made of an oxide semiconductor with a low leakage current such as In—Ga—Zn—O.

For example, PTL 1 discloses a display device having a hybrid structure in which a first TFT using a polysilicon semiconductor and a second TFT using an oxide semiconductor are formed on a substrate.

### CITATION LIST

### Patent Literature

PTL 1: JP 2020-17558 A

### SUMMARY

### Technical Problem

In an organic EL display device in which six TFTs of an initialization transistor, a threshold voltage compensation transistor, a write control transistor, a drive transistor, a power supply control transistor, and a light emission control transistor are provided for each subpixel, it is proposed to use an oxide semiconductor for the initialization transistor and the threshold voltage compensation transistor, and to use polysilicon for the write control transistor, the drive transistor, the power supply control transistor, and the light emission control transistor. Here, since the threshold voltage compensation transistor using the oxide semiconductor is an N-channel type, a voltage of a gate electrode (node G) of the drive transistor electrically connected to the threshold voltage compensation transistor is pulled to a negative side due to feed-through that occurs when the threshold voltage compensation transistor is off and due to an N-type capacitor formed at an intersection of a wiring line connected to the gate electrode of the drive transistor and a scanning signal line for transmitting a scanning signal to the N-channel transistor. When this happens, it is difficult for the drive transistor in the subpixel to produce a black potential in an unlighted state, causing display unevenness. Therefore, a measure is taken to raise the voltage at the node G by forming a P-type capacitor using a scanning signal line for transmitting a scanning signal to a P-channel type transistor and electrically connecting the P-type capacitor to the gate electrode of the drive transistor. However, since the P-type capacitor is formed separately in a portion where the scanning signal line and a metal layer overlap, and a portion where the scanning signal line and a wiring line layer made of an oxide semiconductor overlap, an electric capacitance thereof varies due to manufacturing variations (e.g., variations in a line width of the metal layer). When this happens, the voltage at the node G cannot be raised stably, resulting in display unevenness, and thus there is room for improvement.

The disclosure has been made in view of points mentioned above, and an object of the disclosure is to suppress variations in the electric capacitance of the P-type capacitor and stably raise the voltage of the gate electrode of the drive transistor.

### Solution to Problem

In order to achieve the above object, a display device according to the disclosure includes a base substrate and a thin film transistor layer provided on the base substrate, the thin film transistor layer being formed by sequentially layering a first semiconductor film made of polysilicon, a first inorganic insulating film, a first metal film, a second inorganic insulating film, a second metal film, a second semiconductor film made of an oxide semiconductor, a third inorganic insulating film, a third metal film, a fourth inorganic insulating film, and a fourth metal film, in which subpixels constitute a display region, the thin film transistor layer includes, for each of the subpixels, first transistors, each of the first transistors including a first semiconductor layer formed of the first semiconductor film, in which a first conductor region and a second conductor region are located apart from each other and a first channel region is located between the first conductor region and the second conductor region, and a first gate electrode formed of the first metal film and overlapping the first channel region, and second transistors, each of the second transistors including a second semiconductor layer formed of the second semiconductor film, in which a third conductor region and a fourth conductor region are located apart from each other and a second channel region is located between the third conductor region and the fourth conductor region, and a second gate electrode formed of the third metal film and overlapping the second channel region, as the first transistors, a write control transistor, a drive transistor, a power supply control transistor, and a light emission control transistor are provided, as the second transistors, an initialization transistor and a threshold voltage compensation transistor are provided, the third conductor region in the initialization transistor and the third conductor region in the threshold voltage compensation transistor are electrically connected via a first wiring line formed of the second semiconductor film, the first gate electrode of the drive transistor is electrically connected to the first wiring line via a second wiring line formed of the fourth metal film, in each of the subpixels, a first scanning signal line electrically connected to the first gate electrode of the write control transistor and formed of the first metal film, a second scanning signal line electrically connected to the second gate electrode of the threshold voltage compensation transistor on one side of the first scanning signal line and formed of the third metal film, and another second scanning signal line electrically connected to the second gate electrode of the initialization transistor on another side of the first scanning signal line and formed of the third metal film extend parallel to each other, a third wiring line formed of the second metal film is electrically connected to the second wiring line, and the first wiring line covers the third wiring line at least above the first scanning signal line.

### Advantageous Effects of Disclosure

According to the disclosure, it is possible to suppress variations in the electric capacitance of the P-type capacitor and stably raise the voltage of the gate electrode of the drive transistor.

### BRIEF DESCRIPTION OF DRAWINGS

FIG. 1 is a block diagram of an overall configuration of an organic EL display device according to a first embodiment of the disclosure.

FIG. 2 is an equivalent circuit diagram of a pixel circuit of a TFT layer constituting the organic EL display device according to the first embodiment of the disclosure.

FIG. 3 is a plan view of the TFT layer constituting the organic EL display device according to the first embodiment of the disclosure.

FIG. 4 is a cross-sectional view of the organic EL display device according to the first embodiment of the disclosure.

FIG. 5 is a cross-sectional view schematically illustrating a structure of a layered film of the TFT layer constituting the organic EL display device according to the first embodiment of the disclosure.

FIG. 6 is a cross-sectional view of the TFT layer taken along line VI-VI in FIG. 3.

FIG. 7 is a timing chart for explaining an operation of the pixel circuit of the organic EL display device according to the first embodiment of the disclosure.

FIG. 8 is a plan view of a TFT layer constituting an organic EL display device according to a second embodiment of the disclosure corresponding to FIG. 3.

### DESCRIPTION OF EMBODIMENTS

Embodiments of a technique according to the disclosure will be described below in detail with reference to the drawings. Note that the technique according to the disclosure is not limited to the embodiments to be described below.

### First Embodiment

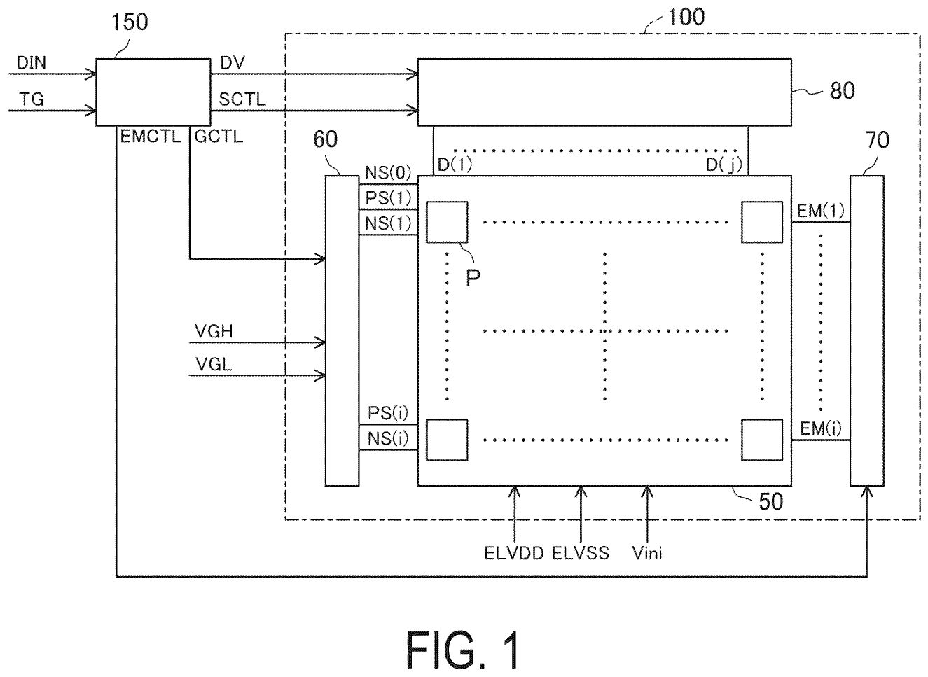

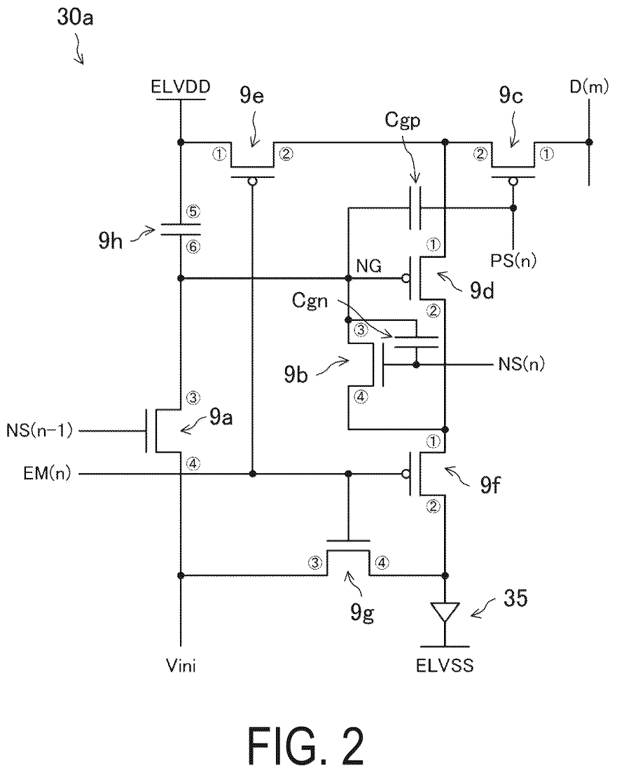

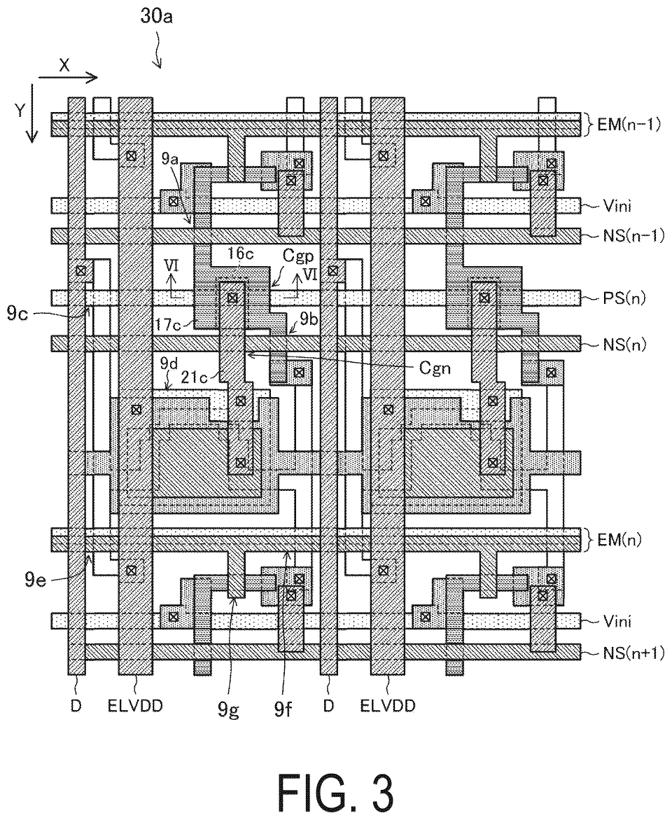

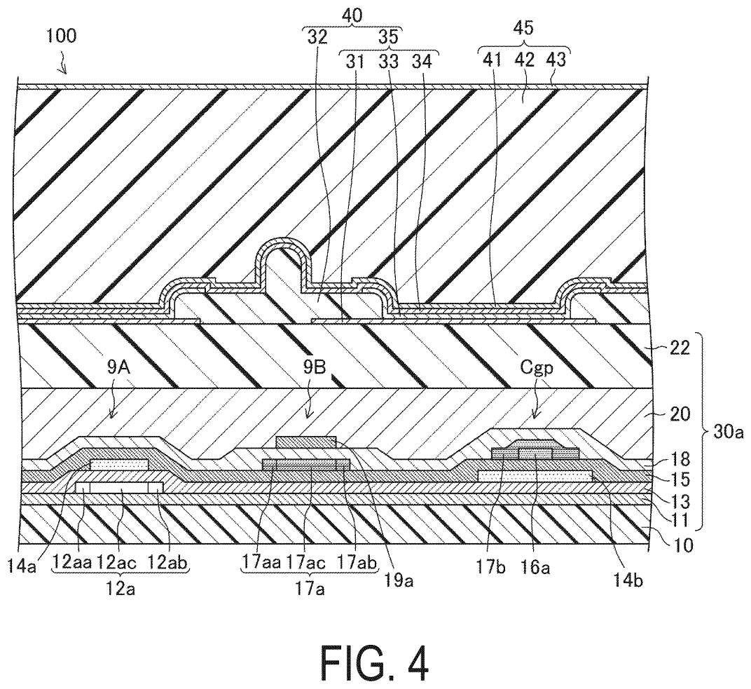

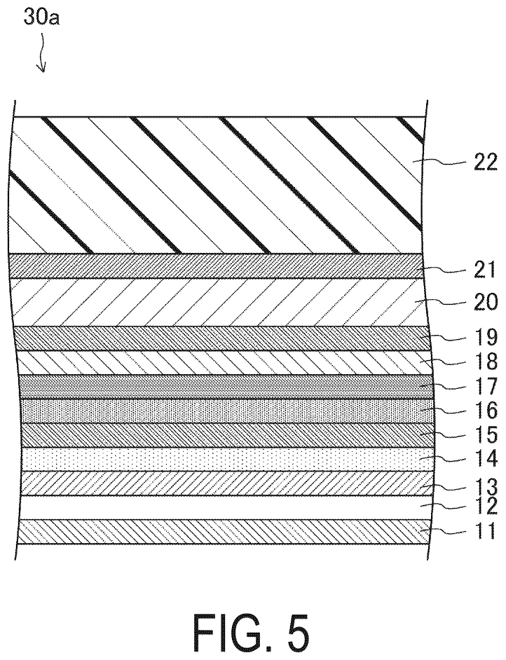

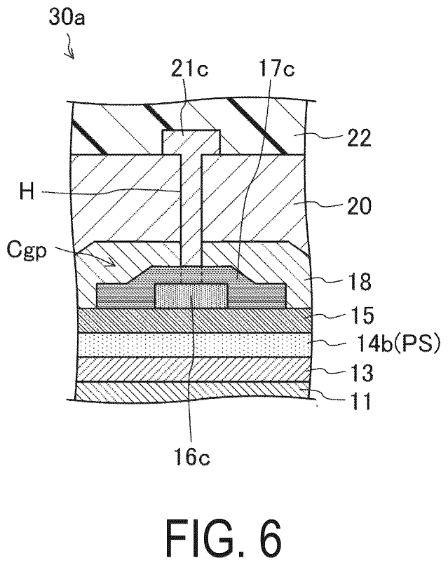

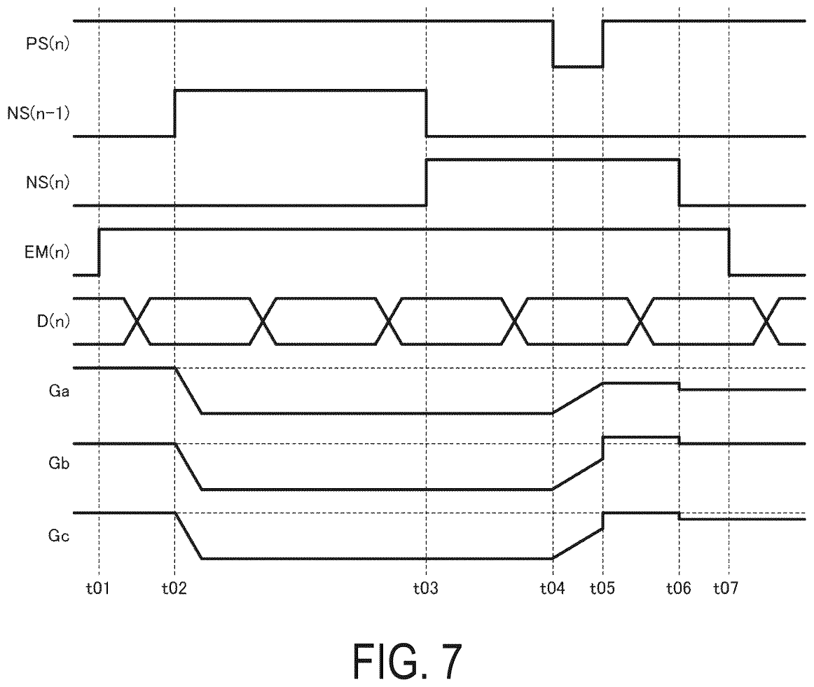

FIG. 1 to FIG. 7 illustrate a display device according to a first embodiment of the disclosure. Note that, in each of the following embodiments, an organic EL display device including an organic EL element layer is exemplified as a display device including a light-emitting element layer. Here, FIG. 1 is a block diagram of an overall configuration of an organic EL display device 100 according to the present embodiment. FIG. 2 is an equivalent circuit diagram of a pixel circuit of a TFT layer 30a constituting the organic EL display device 100. FIG. 3 is a plan view of the TFT layer 30a. Further, FIG. 4 is a cross-sectional view of the organic EL display device 100. FIG. 5 is a cross-sectional view schematically illustrating a structure of a layered film of the TFT layer 30a. FIG. 6 is a cross-sectional view of the TFT layer 30a taken along line VI-VI in FIG. 3. FIG. 7 is a timing chart for describing an operation of the pixel circuit of the organic EL display device 100. Note that, in the cross-sectional views in FIG. 4 and FIG. 5, constituent elements corresponding to those in the plan view in FIG. 3 are hatched in the same manner as in the plan view in FIG. 3.

As illustrated in FIG. 1, the organic EL display device 100 is provided with a display region 50 in which a plurality of subpixels P are provided in a matrix shape, and a gate driver 60, an emission driver 70, and a source driver 80 provided in a frame region around the display region 50. Note that, as illustrated in FIG. 1, a display control circuit 150 that is electrically connected to the gate driver 60, the emission driver 70, and the source driver 80 is provided outside the organic EL display device 100.

As illustrated in FIG. 4, the organic EL display device 100 includes a resin substrate 10 provided as a base substrate, the TFT layer 30a provided on the resin substrate 10, an organic EL element layer 40 provided as a light-emitting element layer on the TFT layer 30a, and a sealing film 45 provided on the organic EL element layer 40.

The resin substrate 10 is formed of, for example, a polyimide resin.

As illustrated in FIG. 4, the TFT layer 30a includes a base coat film 11 provided on the resin substrate 10, four P-channel type first transistors 9A, three N-channel type second transistors 9B, and one capacitor 9h (see FIG. 2) provided on the base coat film 11 for each subpixel P, and a flattening film 22 provided on the first transistors 9A, the second transistors 9B, and the capacitor 9h. In the TFT layer 30a, as illustrated in FIG. 5, the base coat film 11, a first semiconductor film 12, a first gate insulating film 13, a first metal film 14, a first interlayer insulating film 15, a second metal film 16, a second semiconductor film 17, a second gate insulating film 18, a third metal film 19, a second interlayer insulating film 20, a fourth metal film 21, and the flattening film 22 are sequentially layered on the resin substrate 10. Here, the base coat film 11, the first gate insulating film 13 provided as a first inorganic insulating film, the first interlayer insulating film 15 provided as a second inorganic insulating film, the third gate insulating film 18 provided as a third inorganic insulating film, and the second interlayer insulating film 20 provided as a fourth inorganic insulating film are each formed of, for example, a single-layer film of silicon nitride, silicon oxide, or silicon oxynitride, or a layered film thereof. Note that at least the first interlayer insulating film 15 and the third gate insulating film 18 on sides of a second semiconductor layer 17a, which will be described below, are composed of silicon oxide films, respectively. Further, the first semiconductor film 12 is made of polysilicon, and is, for example, a film for forming a first semiconductor layer 12a and the like to be described below. The first metal film 14 is, for example, a film for forming a first gate electrode 14a and the like to be described below. The second metal film 16 is, for example, a film for forming a third wiring line 16c and the like to be described below. The second semiconductor film 17 is made of an oxide semiconductor and is a film for forming, for example, the second semiconductor layer 17a, a first wiring line 17c, and the like, which will be described later, and has a film thickness (e.g., about 30 nm) smaller than a film thickness of the second metal film 16 (e.g., about 250 nm). The third metal film 19 is, for example, a film for forming a second gate electrode 19a and the like to be described below. The fourth metal film 21 is, for example, a film for forming a second wiring line 21c and the like to be described below.

As illustrated in FIG. 1, i pieces of first scanning signal lines PS(1) to PS(i), (i+1) pieces of second scanning signal lines NS(0) to NS(i), i pieces of light emission control lines EM(1) to EM(i), and j pieces of data signal lines D(1) to D(j) are provided in the display region 50 of the TFT layer 30a. Note that each of i and j is an integer equal to or greater than 2, n is an integer in a range from 1 to i, and m is an integer in a range from 1 to j. Further, in FIG. 1, the first scanning signal lines PS, the second scanning signal lines NS, and the data signal lines D are not illustrated in the display region 50. Here, the first scanning signal lines PS(1) to PS(i) are signal lines for transmitting first scanning signals, which are control signals for the P-channel type transistors. Further, the second scanning signal lines NS(0) to NS(i) are signal lines for transmitting second scanning signals, which are control signals for the N-channel type transistors. Further, the light emission control lines EM(1) to EM(i) are signal lines for transmitting light emission control signals. Note that, as illustrated in FIG. 3, the first scanning signal lines PS(1) to PS(i), the second scanning signal lines NS(0) to NS(i), and the light emission control lines EM(1) to EM(i) are provided in parallel (side-by-side) with each other. Further, as illustrated in FIG. 3, the first scanning signal lines PS(1) to PS(i) and the data signal lines D(1) to D(j) are provided to be orthogonal to each other. Further, in a timing chart in FIG. 7 to be described below, the reference signs PS(1) to PS(i) are also assigned to the first scanning signals supplied to each of the first scanning signal lines PS(1) to PS(i), the reference signs NS(0) to NS(i) are also assigned to the second scanning signals supplied to each of the second scanning signal lines NS(0) to NS(i), the reference signs EM(1) to EM(i) are also assigned to the light emission control signals supplied to each of the light emission control lines EM(1) to EM(i), and the reference signs D(1) to D(j) are also assigned to data signals (data voltages) supplied to each of the data signal lines D(1) to D(j).

Furthermore, a power supply line that supplies a high-level power supply voltage ELVDD (hereinafter, referred to as a “high-level power supply line”) for driving an organic EL element 35 to be described later, a power supply line that supplies a low-level power supply voltage ELVSS (hereinafter, referred to as a “low-level power supply line”) for driving the organic EL element 35, and a power supply line that supplies an initialization voltage Vini (hereinafter, referred to as an “initialization power supply line”) are provided in the display region 50 of the TFT layer 30a. Note that, in the present embodiment, as necessary, the reference sign ELVDD is also assigned to the high-level power supply line, the reference sign ELVSS is also assigned to the low-level power supply line, and the reference sign Vini is also assigned to the initialization power supply line. The high-level power supply voltage ELVDD, the low-level power supply voltage ELVSS, and the initialization voltage Vini are supplied from power source circuits that are not illustrated.

As illustrated in FIG. 4, the first transistor 9A includes the first semiconductor layer 12a provided on the base coat film 11, and the first gate electrode 14a provided on the first semiconductor layer 12a with the first gate insulating film 13 interposed therebetween.

The first semiconductor layer 12a is formed of the first semiconductor film 12 made of polysilicon such as low temperature polysilicon (LTPS), and as illustrated in FIG. 4, includes a first conductor region 12aa and a second conductor region 12ab located so as to be separated from each other, and a first channel region 12ac located between the first conductor region 12aa and the second conductor region 12ab.

The first gate electrode 14a is formed in the first metal film 14 and, as illustrated in FIG. 4, is provided so as to overlap the first channel region 12ac of the first semiconductor layer 12a and is configured to control conduction between the first conductor region 12aa and the second conductor region 12ab of the first semiconductor layer 12a.

Note that, as necessary, in the first transistor 9A, a first terminal electrode and a second terminal electrode are provided, which are formed on the second interlayer insulating film 20 and are electrically connected to the first conductor region 12aa and the second conductor region 12ab of the first semiconductor layer 12a, respectively, via two contact holes formed in a layered film of the first gate insulating film 13, the first interlayer insulating film 15, the second gate insulating film 18, and the second interlayer insulating film 20.

As illustrated in FIG. 4, the second transistor 9B includes the second semiconductor layer 17a provided on the first interlayer insulating film 15, and the second gate electrode 19a provided on the second semiconductor layer 17a with the second gate insulating film 18 interposed therebetween.

The second semiconductor layer 17a is made of, for example, an In—Ga—Zn—O based oxide semiconductor, and includes, as illustrated in FIG. 4, a third conductor region 17aa and a fourth conductor region 17ab located so as to be separated from each other, and a second channel region 17ac located between the third conductor region 17aa and the fourth conductor region 17ab. Here, the In—Ga—Zn—O based semiconductor is ternary oxide of indium (In), gallium (Ga), and zinc (Zn), and a ratio (a composition ratio) of each of In, Ga, and Zn is not particularly limited to a specific value. The In—Ga—Zn—O based semiconductor may be an amorphous semiconductor or may be a crystalline semiconductor. Note that a crystalline In—Ga—Zn—O based semiconductor in which a c-axis is oriented substantially perpendicular to a layer surface is preferable as the crystalline In—Ga—Zn—O based semiconductor. In place of the In—Ga—Zn—O based semiconductor, another oxide semiconductor may be included. Examples of other oxide semiconductors may include an In—Sn—Zn—O based semiconductor (for example, In₂O₃—SnO₂—ZnO; InSnZnO). The In—Sn—Zn—O based semiconductor is ternary oxide of indium (In), tin (Sn), and zinc (Zn). Alternatively, examples of other oxide semiconductors may include an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, cadmium oxide (CdO), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, an In—Ga—Zn—Sn—O based semiconductor, InGaO₃(ZnO)₅, magnesium zinc oxide (MgₓZn₁₋ₓO), and cadmium zinc oxide (CdₓZn₁₋ₓO). Note that as the Zn—O based semiconductor, a semiconductor in a non-crystalline (amorphous) state of ZnO to which one kind or a plurality of kinds of impurity elements among group 1 elements, group 13 elements, group 14 elements, group 15 elements, group 17 elements, and the like are added, a polycrystalline state, or a microcrystalline state in which the non-crystalline state and the polycrystalline state are mixed, or a semiconductor to which no impurity element is added can be used.

The second gate electrode 19a is formed of the third metal film 19, is, as illustrated in FIG. 4, provided so as to overlap the second channel region 17ac of the second semiconductor layer 17a, and is configured to control conduction between the third conductor region 17aa and the fourth conductor region 17ab of the second semiconductor layer 17a.

Note that, as necessary, in the second transistor 9B, a third terminal electrode and a fourth terminal electrode are provided, which are formed on the second interlayer insulating film 20 and are electrically connected to the third conductor region 17aa and the fourth conductor region 17ab of the second semiconductor layer 17a, respectively, via two contact holes formed in the layered film of the second gate insulating film 18 and the second interlayer insulating film 20, and a conductive layer formed of the second metal film 16 so as to be in contact with the third conductor region 17aa and the fourth conductor region 17ab.

In the present embodiment, a write control transistor 9c, a drive transistor 9d, a power supply control transistor 9e, and a light emission control transistor 9f, which will be described below, are provided as the four P-channel type first transistors 9A including the first semiconductor layer 12a made of polysilicon, and an initialization transistor 9a, a threshold voltage compensation transistor 9b, and an anode discharge transistor 9g, which will be described below, are provided as the three N-channel type second transistors 9B including the second semiconductor layer 17a made of an oxide semiconductor (see FIG. 2). Note that, in the equivalent circuit diagram in FIG. 2, the first terminal electrode (the first conductor region 12aa) and the second terminal electrode (the second conductor region 12ab) of each of the transistors 9c, 9d, 9e, and 9f are indicated by circled numbers \textcircled{1} and \textcircled{2}, the third terminal electrode (the third conductor region 17aa) and the fourth terminal electrode (the fourth conductor region 17ab) of each of the transistors 9a, 9b, and 9g are indicated by circled numbers \textcircled{3} and \textcircled{4}, and a first capacitance electrode and a second capacitance electrode of the capacitor 9h to be described later are indicated by circled numbers \textcircled{5} and \textcircled{6}.

As illustrated in FIG. 2 and FIG. 3, the initialization transistor 9a includes the second gate electrode 19a, which is part of the second scanning signal line NS(n−1) in an (n−1)th row, and is thereby electrically connected to the second scanning signal line NS(n−1), the third terminal electrode (the third conductor region 17aa) electrically connected to the third terminal electrode (the third conductor region 17aa) of the threshold voltage compensation transistor 9b, the first gate electrode 14a of the drive transistor 9d, and the second capacitance electrode of the capacitor 9h, and the fourth terminal electrode (the fourth conductor region 17ab) electrically connected to the initialization power supply line Vini. Here, the third conductor region 17aa of the initialization transistor 9a and the third conductor region 17aa of the threshold voltage compensation transistor 9b are electrically connected via the first wiring line 17c formed of the second semiconductor film 17, as illustrated in FIG. 3. Note that the first wiring line 17c is constituted of the third conductor regions 17aa of the initialization transistor 9a and the threshold voltage compensation transistor 9b. The fourth conductor region 17ab of the initialization transistor 9a is electrically connected to the initialization power supply line Vini formed of the first metal film 14 via a conductive layer formed of the second metal film 16 layered below the fourth conductor region 17ab and a contact hole formed in the first interlayer insulating film 15 layered below the conductive layer. The second scanning signal line NS functioning as the second gate electrode 19a of the initialization transistor 9a is formed of the third metal film 19.

As illustrated in FIG. 3, the first wiring line 17c constitutes a P-type capacitor Cgp at a portion overlapping the first scanning signal line PS(n). Here, as illustrated in FIG. 6, the P-type capacitor Cgp includes the first scanning signal line PS composed of the wiring line layer 14b formed of the first metal film 14, the first interlayer insulating film 15 provided so as to cover the first scanning signal line PS, the third wiring line 16c formed of the second metal film 16 on the first interlayer insulating film 15, and the first wiring line 17c provided directly on the third wiring line 16c so as to cover the third wiring line 16c at least above the first scanning signal line PS. The P-type capacitor Cgp is configured to raise the voltage of the first gate electrode 14a of the drive transistor 9d, that is, the voltage at the node G (NG in FIG. 2), when the first scanning signal line PS(n) changes from a low level to a high level.

As illustrated in FIG. 2 and FIG. 3, the threshold voltage compensation transistor 9b includes the second gate electrode 19a, which is part of the second scanning signal line NS(n) in an n-th row, and is thereby electrically connected to the second scanning signal line NS(n), the third terminal electrode (the third conductor region 17aa) electrically connected to the third terminal electrode of the initialization transistor 9a, the first gate electrode 14a of the drive transistor 9d, and the second capacitance electrode of the capacitor 9h, and the fourth terminal electrode (the fourth conductor region 17ab) electrically connected to the second terminal electrode (the second conductor region 12ab) of the drive transistor 9d and the first terminal electrode (the first conductor region 12aa) of the light emission control transistor 9f. Here, the fourth conductor region 17ab of the threshold voltage compensation transistor 9b is electrically connected to the second conductor region 12ab of the drive transistor 9d via a conductive layer formed of the second metal film 16 layered below the fourth conductor region 17ab and a contact hole formed in a layered film of the first interlayer insulating film 15 and the first gate insulating film 13 layered below the conductive layer.

As illustrated in FIG. 2 and FIG. 3, the write control transistor 9c includes the first gate electrode 14a, which is part of the first scanning signal line PS(n) in the n-th row, and is thereby connected to the first scanning signal line PS(n), the first terminal electrode (the first conductor region 12aa) electrically connected to the data signal line D(m) in an m-th column, and the second terminal electrode (the second conductor region 12ab) electrically connected to the first terminal electrode (the first conductor region 12aa) of the drive transistor 9d and the second terminal electrode (the second conductor region 12ab) of the power supply control transistor 9e. Here, the first scanning signal line PS functioning as the first gate electrode 14a of the write control transistor 9c is formed of the first metal film 14.

As illustrated in FIG. 2 and FIG. 3, the drive transistor 9d includes the first gate electrode 14a electrically connected to the third terminal electrode (the third conductor region 17aa) of the initialization transistor 9a, the third terminal electrode (the third conductor region 17aa) of the threshold voltage compensation transistor 9b, and the second capacitance electrode of the capacitor 9h, the first terminal electrode (the first conductor region 12aa) electrically connected to the second terminal electrode (the second conductor region 12ab) of the write control transistor 9c and the second terminal electrode (the second conductor region 12ab) of the power supply control transistor 9e, and the second terminal electrode (the second conductor region 12ab) electrically connected to the fourth terminal electrode (the fourth conductor region 17ab) of the threshold voltage compensation transistor 9b and the first terminal electrode (the first conductor region 12aa) of the light emission control transistor 9f. Note that the first terminal electrode (the first conductor region 12aa) of the drive transistor 9d receives the high-level power supply voltage ELVDD during a period when the organic EL element 35 is caused to emit light and receives the data signal D(m) during a period when data is written to the capacitor 9h. Here, the first gate electrode 14a of the drive transistor 9d is electrically connected to the respective third conductor regions 17aa of the initialization transistor 9a and the threshold voltage compensation transistor 9b, that is, the first wiring line 17c, via the second wiring line 21c formed of the fourth metal film 21. Note that the first conductor region 12aa of the drive transistor 9d is provided integrally with the second conductor region 12ab of the write control transistor 9c and the second conductor region 12ab of the power supply control transistor 9e, and is thereby electrically connected to the second conductor region 12ab of the write control transistor 9c and the second conductor region 12ab of the power supply control transistor 9e. The second conductor region 12ab of the drive transistor 9d is provided integrally with the first conductor region 12aa of the light emission control transistor 9f and is thereby electrically connected to the first conductor region 12aa of the light emission control transistor 9f.

As illustrated in FIG. 3, the second wiring line 21c is provided so as to intersect (be orthogonal to) the second scanning signal line NS(n) located on one side (a lower side in the figure) of the first scanning signal line PS(n), and forms an N-type capacitor Cgn in a portion overlapping the second scanning signal line NS(n). Here, the N-type capacitor Cgn includes the second scanning signal line NS formed of the third metal film 19, the second interlayer insulating film 20 provided so as to cover the second scanning signal line NS, and the second wiring line 21c provided on the second interlayer insulating film 20. The N-type capacitor Cgn is configured to lower the voltage of the first gate electrode 14a of the drive transistor 9d, that is, the voltage at the node G (NG) when the second scanning signal line NS(n) changes from a high level to a low level. Note that the electric capacitance of the N-type capacitor Cgn is designed to be smaller than the electric capacitance of the P-type capacitor Cgp. As illustrated in FIG. 6, the second wiring line 21c is electrically connected to the third wiring line 16c via a contact hole H formed in the layered film of the second gate insulating film 18 and the second interlayer insulating film 20, and the first wiring line 17c. As illustrated in FIG. 6, the contact hole H is located above the first scanning signal line PS and may be provided so as to penetrate the first wiring line 17c. That is, as illustrated in FIG. 3 and FIG. 6, the contact hole H is provided in a region overlapping the third wiring line 16c in a plan view and in a region where the first wiring line 17c and the third wiring line 16c overlap in a plan view, and may be provided so as to penetrate the first wiring line 17c.

As illustrated in FIG. 2 and FIG. 3, the power supply control transistor 9e includes the first gate electrode 14a, which is part of the light emission control line EM(n) in the n-th row, and is thereby electrically connected to the light emission control line EM(n), the first terminal electrode (the first conductor region 12aa) electrically connected to the high-level power supply line ELVDD and the first capacitance electrode of the capacitor 9h, and the second terminal electrode (the second conductor region 12ab) electrically connected to the second terminal electrode (the second conductor region 12ab) of the write control transistor 9c and the first terminal electrode (the first conductor region 12aa) of the drive transistor 9d. Note that, as illustrated in FIG. 3, the light emission control line EM includes a wiring line layer formed of the first metal film 14 and a wiring line layer formed of the third metal film 19.

As illustrated in FIG. 2 and FIG. 3, the light emission control transistor 9f includes the first gate electrode 14a, which is part of the light emission control line EM(n) in the n-th row, and is thereby electrically connected to the light emission control line EM(n), the first terminal electrode (the first conductor region 12aa) electrically connected to the fourth terminal electrode (the fourth conductor region 17ab) of the threshold voltage compensation transistor 9b and the second terminal electrode (the second conductor region 12ab) of the drive transistor 9d, and the second terminal electrode (the second conductor region 12ab) electrically connected to the fourth terminal electrode (the fourth conductor region 17ab) of the anode discharge transistor 9g and a first electrode 31, which will be described later, of the organic EL element 35. Here, the second conductor region 12ab of the light emission control transistor 9f is electrically connected to the fourth conductor region 17ab of the anode discharge transistor 9g via a conductive layer formed of the second metal film 16 layered below the fourth conductor region 17ab of the anode discharge transistor 9g and a contact hole formed in the layered film of the first interlayer insulating film 15 and the first gate insulating film 13 layered below the conductive layer.

As illustrated in FIG. 2 and FIG. 3, the anode discharge transistor 9g includes the second gate electrode 19a, which is a protrusion to a side of the light emission control line EM(n) in the n-th row, and is thereby electrically connected to the light emission control line EM(n), the third terminal electrode (the third conductor region 17aa) electrically connected to the initialization power supply line Vini, and the fourth terminal electrode (the fourth conductor region 17ab) electrically connected to the second terminal electrode (the second conductor region 12ab) of the light emission control transistor 9f and the first electrode 31 of the organic EL element 35. Here, the third conductor region 17aa of the anode discharge transistor 9g is electrically connected to the initialization power supply line Vini via a conductive layer formed of the second metal film 16 layered below the third conductor region 17aa and a contact hole formed in the first interlayer insulating film 15 layered below the conductive layer. The fourth conductor region 17ab of the anode discharge transistor 9g is electrically connected to the first electrode 31 via a conductive layer formed of the second metal film 16 layered below the fourth conductor region 17ab and a contact hole formed in the layered film of the second gate insulating film 18 and the second interlayer insulating film 20, and a conductive layer formed of the fourth metal film 21 and a contact hole formed in the flattening film 22.

The capacitor 9h includes, for example, the first capacitance electrode formed of the second metal film 16, the second capacitance electrode formed of the first metal film 14, and the first interlayer insulating film 15 provided between the first capacitance electrode and the second capacitance electrode. Here, in the capacitor 9h, the first capacitance electrode is electrically connected to the high-level power supply line ELVDD and the first terminal electrode (the first conductor region 12aa) of the power supply control transistor 9e, and the second capacitance electrode is electrically connected to the third terminal electrode (the third conductor region 17aa) of the initialization transistor 9a, the third terminal electrode (the third conductor region 17aa) of the threshold voltage compensation transistor 9b, and the first gate electrode 14a of the drive transistor 9d. Note that the first capacitance electrode of the capacitor 9h is electrically connected to the high-level power supply line ELVDD formed of the fourth metal film via a contact hole formed in the layered film of the second gate insulating film 18 and the second interlayer insulating film 20. The second capacitance electrode of the capacitor 9h is provided integrally with the first gate electrode 14a of the drive transistor 9d and is thereby electrically connected to the first gate electrode 14a of the drive transistor 9d. As the capacitor 9h, in addition to a first capacitor that includes the first capacitance electrode formed of the second metal film 16, the second capacitance electrode formed of the first metal film 14, and the first interlayer insulating film 15 provided between the first capacitance electrode and the second capacitance electrode, as described above, a second capacitor may be provided including the first capacitance electrode formed of the second metal film 16, a third capacitance electrode formed of the third metal film 19, and the second gate insulating film 18 provided between the first capacitance electrode and the third capacitance electrode.

The flattening film 22 has a flat surface in the display region 50, and is made of, for example, an organic resin material such as a polyimide resin or an acrylic resin, or a polysiloxane-based spin on glass (SOG) material.

As illustrated in FIG. 4, the organic EL element layer 40 includes a plurality of the organic EL elements 35 provided as a plurality of light-emitting elements arrayed in a matrix shape in correspondence with the plurality of subpixels P, and an edge cover 32 provided in a lattice pattern shared by all the subpixels P so as to cover peripheral end portions of the first electrode 31 of each of the organic EL elements 35.

As illustrated in FIG. 4, the organic EL element 35 includes, in each of the subpixels P, the first electrode 31 (anode electrode) provided on the flattening film 22 of the TFT layer 30a, an organic EL layer 33 provided on the first electrode 31, and a second electrode 34 (cathode electrode) provided on the organic EL layer 33.

The first electrode 31 is electrically connected to the second conductor region of the light emission control transistor 9f of each of the subpixels P, through a contact hole formed in the flattening film 22. Further, the first electrode 31 functions to inject holes (positive holes) into the organic EL layer 33. Further, the first electrode 31 is preferably made of a material having a large work function to improve the efficiency of hole injection into the organic EL layer 33. Here, examples of materials constituting the first electrode 31 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Further, examples of the materials constituting the first electrode 31 may include an alloy such as astatine (At)/astatine oxide (AtO₂), or the like. Furthermore, examples of the materials constituting the first electrode 31 may include electrically conductive oxide such as tin oxide (SnO), zinc oxide (ZnO), indium tin oxide (ITO), and indium zinc oxide (IZO). Additionally, the first electrode 31 may be formed by layering a plurality of layers made of any of the materials described above. Note that examples of compound materials having a high work function include indium tin oxide (ITO) and indium zinc oxide (IZO).

The organic EL layer 33 includes a hole injection layer, a hole transport layer, a light-emitting layer, an electron transport layer, and an electron injection layer provided in this order on the first electrode 31. Here, the hole injection layer is also referred to as an anode electrode buffer layer, and functions to reduce an energy level difference between the first electrode 31 and the organic EL layer 33 to thus improve the hole injection efficiency into the organic EL layer 33 from the first electrode 31. Note that examples of materials constituting the hole injection layer include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, stilbene derivatives, and the like. Further, the hole transport layer functions to improve the hole transport efficiency from the first electrode 31 to the organic EL layer 33. Note that examples of materials constituting the hole transport layer include porphyrin derivatives, aromatic tertiary amine compounds, styrylamine derivatives, polyvinyl carbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, zinc selenide, and the like. Further, the light-emitting layer is a region where holes and electrons are injected from the first electrode 31 and the second electrode 34, respectively, and where the holes and the electrons recombine, when a voltage is applied by the first electrode 31 and the second electrode 34. Note that examples of materials constituting the light-emitting layer include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, polysilane, and the like. Further, the electron transport layer functions to efficiently move the electrons to the light-emitting layer. Note that examples of materials constituting the electron transport layer include, as organic compounds, oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, metal oxinoid compounds, and the like. Further, the electron injection layer functions to reduce an energy level difference between the second electrode 34 and the organic EL layer 33 to thus improve the electron injection efficiency into the organic EL layer 33 from the second electrode 34, and, due to this function, the drive voltage of the organic EL element 35 can be reduced. Note that examples of materials constituting the electron injection layer include inorganic alkaline compounds, such as lithium fluoride (LiF), magnesium fluoride (MgF₂), calcium fluoride (CaF₂), strontium fluoride (SrF₂), and barium fluoride (BaF₂); aluminum oxide (Al₂O₃); and stronium oxide (SrO).

As illustrated in FIG. 4, the second electrode 34 is provided in common to all of the subpixels P so as to cover each of the organic EL layers 33 and the edge cover 32. Further, the second electrode 34 functions to inject electrons into the organic EL layer 33. Further, the second electrode 34 is preferably formed of a material having a low work function to improve the efficiency of electron injection into the organic EL layer 33. Further, as illustrated in FIG. 2, the second electrode 34 is electrically connected to the low-level power supply line ELVSS. Here, examples of a material constituting the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Further, the second electrode 34 may be formed of an alloy, such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), lithium fluoride (LiF)/calcium (Ca)/aluminum (Al) and the like. Further, the second electrode 34 may be formed of an electrically conductive oxide such as tin oxide (SnO), zinc oxide (ZnO), indium tin oxide (ITO), and indium zinc oxide (IZO). Further, the second electrode 34 may be formed by layering a plurality of layers formed of any of the materials described above. Note that examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

The edge cover 32 is made of, for example, an organic resin material such as a polyimide resin or an acrylic resin, or an SOG material of a polysiloxane based.

As illustrated in FIG. 4, the sealing film 45 is provided so as to cover the second electrode 34, includes a first inorganic sealing film 41, an organic sealing film 42, and a second inorganic sealing film 43 layered on the second electrode 34 in that order, and functions to protect the organic EL layer 33 of the organic EL element layer 35 from moisture, oxygen, and the like.

The first inorganic sealing film 41 and the second inorganic sealing film 43 are constituted of, for example, an inorganic insulating film such as a silicon nitride film, a silicon oxide film, or a silicon oxynitride film.

The organic sealing film 42 is made of, for example, an organic resin material such as an acrylic resin, an epoxy resin, a silicone resin, a polyurea resin, a parylene resin, a polyimide resin, a polyamide resin, or the like.

Next, an operation of the organic EL display device 100 having the above-described configuration will be described.

### Operation of Peripheral Circuit

As illustrated in FIG. 1, the display control circuit 150 receives an input image signal DIN and a timing signal group (a horizontal synchronization signal, a vertical synchronization signal, and the like) TG transmitted from the outside, and outputs a digital video signal DV, a gate control signal GCTL for controlling the operation of the gate driver 60, an emission driver control signal EMCTL for controlling the operation of the emission driver 70, and a source control signal SCTL for controlling the operation of the source driver 80. Here, the gate control signal GCTL includes a gate start pulse signal, a gate clock signal, and the like. Further, the emission driver control signal EMCTL includes an emission start pulse signal, an emission clock signal, and the like. Further, the source control signal SCTL includes a source start pulse signal, a source clock signal, a latch strobe signal, and the like.

The gate driver 60 is electrically connected to the first scanning signal lines PS(1) to PS(i) and the second scanning signal lines NS(0) to NS(i). Then, based on the gate control signal GCTL output from the display control circuit 150, the gate driver 60 applies the first scanning signal to the first scanning signal lines PS(1) to PS(i), and the second scanning signal to the second scanning signal lines NS(0) to NS(i).

The emission driver 70 is electrically connected to the light emission control lines EM(1) to EM(i). Then, based on the emission driver control signal EMCTL output from the display control circuit 150, the emission driver 70 applies the light emission control signal to the light emission control lines EM(1) to EM(i).

The source driver 80 includes an j-bit shift register, a sampling circuit, a latch circuit, j pieces of D/A converters, and the like, which are not illustrated. Here, the shift register includes j pieces of cascade-connected registers, and based on the source clock signal, the shift register sequentially transfers a pulse of the source start pulse signal supplied to a first stage register from an input end to an output end, and a sampling pulse is output from the register of each stage according to the transfer of the pulse. Then, the sampling circuit stores the digital video signal DV based on the sampling pulse. Then, in accordance with the latch strobe signal, the latch circuit acquires and holds the digital video signal DV for one row stored in the sampling circuit. Then, the D/A converter is provided corresponding to each of the data signal lines D(1) to D(j), converts the digital video signal DV held in the latch circuit to an analog voltage, and applies the converted analog voltage as a data signal (data voltage) to all the data signal lines D(1) to D(j) simultaneously.

As described above, as a result of the data signal being applied to the data signal lines D(1) to D(j), the first scanning signal being applied to the first scanning signal lines PS(1) to PS(i), the second scanning signal being applied to the second scanning signal lines NS(0) to NS(i), and the first light emission control signal being applied to the first light emission control lines EM(1) to EM(i), an image based on the input image signal DIN is displayed in the display region 50.

### Operation of Pixel Circuit of Display Region

Next, the operation of the pixel circuit of the organic EL display device 100 according to the present embodiment will be described using the timing chart in FIG. 7. Note that the operation of the pixel circuit described here is merely an example, and no limitation thereto is intended.

First, before time t01, the first scanning signal PS(n) is at a high level, and the second scanning signal NS(n−1), the second scanning signal NS(n), and the light emission control signal EM(n) are at a low level. At this time, the power supply control transistor 9e and the light emission control transistor 9f are in an on state, and the anode discharge transistor 9g is in an off state. Accordingly, before time t01, a drive current corresponding to a charging voltage of the capacitor 9h is supplied to the organic EL element 35, and the organic EL element 35 emits light in accordance with the magnitude of the drive current.

At time t01, as a result of the light emission control signal EM(n) changing from the low level to the high level, the power supply control transistor 9e and the light emission control transistor 9f are in the off state. As a result, the supply of the drive current to the organic EL element 35 is cut off, and the organic EL element 35 is thus in an unlighted state. Further, as a result of the light emission control signal EM(n) changing from the low level to the high level, the anode discharge transistor 9g is in the on state. Thus, the voltage of the first electrode 31 of the organic EL element 35 is initialized based on the initialization voltage Vini.

At time t02, as a result of the second scanning signal NS(n−1) changing from the low level to the high level, the initialization transistor 9a is in the on state. As a result, the gate voltage of the drive transistor 9d is initialized. In other words, the gate voltage of the drive transistor 9d becomes equal to the initialization voltage Vini.

At time t03, as a result of the second scanning signal NS(n−1) changing from the high level to the low level, the initialization transistor 9a is in the off state. Further, at time t03, the second scanning signal NS(n) changes from the low level to the high level. Thus, the threshold voltage compensation transistor 9b is in the on state.

At time t04, as a result of the first scanning signal PS(n) changing from the high level to the low level, the write control transistor 9c is in the on state. Here, since the threshold voltage compensation transistor 9b is in the on state at time t03, when the write control transistor 9c is switched to the on state at time t04, the data signal D(m) is input to the second capacitance electrode of the capacitor 9h via the write control transistor 9c, the drive transistor 9d, and the threshold voltage compensation transistor 9b. In this way, the capacitor 9h is charged.

At time t05, as a result of the first scanning signal PS(n) changing from the low level to the high level, the write control transistor 9c is in the off state.

At time t06, as a result of the second scanning signal NS(n) changing from the high level to the low level, the threshold voltage compensation transistor 9b is in the off state.

At time t07, as a result of the light emission control signal EM(n) changing from the high level to the low level, the anode discharge transistor 9g is in the off state, and, at the same time, the power supply control transistor 9e and the light emission control transistor 9f are in the on state. In this way, the drive current corresponding to the charging voltage of the capacitor 9h is supplied to the organic EL element 35, and the organic EL element 35 emits light in accordance with the magnitude of the drive current.

In this way, in the organic EL display device 100, in each of the subpixels P, the organic EL element 35 emits the light at a luminance corresponding to the drive current, and the image display is performed.

Here, behavior of the gate voltage (the voltage at the node G (NG)) of the drive transistor 9d in the organic EL display device 100 will be described. In the timing chart in FIG. 7, Ga indicates behavior of the voltage at the node G (NG) when no P-type capacitor is added to the node G (NG), Gb indicates behavior of the voltage at the node G (NG) in a case of the embodiment in which a stable P-type capacitor is added to the node G (NG), and Gc indicates behavior of the voltage at the node G (NG) when an unstable P-type capacitor is added to the node G (NG) (when the display unevenness described in Technical Problem occurs).

To be specific, before time t02, the voltage at the node G (Ga, Gb, Gc) is at a black potential.

At time t02, as described above, the gate voltage of the drive transistor 9d is initialized, and the voltage at the node G (NG) becomes equal to the initialization voltage Vini in the cases of Ga, Gb, and Gc.

At time t05, as a result of the first scanning signal PS(n) changing from the low level to the high level, the voltage at the node G (NG) rises in the cases of Ga, Gb, and Gc. Here, when no P-type capacitor is added (Ga), the voltage at the node G (NG) rises only to a potential lower than the black potential. When a stable P-type capacitor is added (Gb), the voltage at the node G (NG) rises to a potential higher than the black potential. When an unstable P-type capacitor is added (Gc), the voltage at the node G (NG) rises to the same level as the black potential.

At time t06, as a result of the second scanning signal NS(n) changing from the high level to the low level, the voltage at the node G (NG) drops in the cases of Ga, Gb, and Gc. Here, when no P-type capacitor is added (Ga), the voltage at the node G (NG), which is lower than the black potential, becomes even lower. When a stable P-type capacitor is added (Gb), even when the voltage at the node G (NG) drops, the voltage at the node G (NG) becomes the black potential because the voltage at the node G (NG) is raised in advance. When an unstable P-type capacitor is added (Gc), the voltage at the node G (NG) becomes lower than the black potential.

As described above, in the organic EL display device 100 in the present embodiment, by adding the P-type capacitor having a stable electric capacitance, the voltage of the gate electrode of the drive transistor 9d can be stably raised and the black potential can be ensured.

Next, a method of manufacturing the organic EL display device 100 according to the present embodiment will be described. Note that the method for manufacturing the organic EL display device 100 includes a TFT layer forming step, an organic EL element layer forming step, and a sealing film forming step.

### TFT Layer Forming Step

First, for example, a silicon oxide film (having a thickness of approximately 100 nm) is formed, for example, by plasma chemical vapor deposition (CVD), on the resin substrate 10 formed on a glass substrate, thus forming the base coat film 11.

Subsequently, an amorphous silicon film (having a thickness of approximately 50 nm) is formed by plasma CVD, for example, on the substrate surface on which the base coat film 11 is formed, the amorphous silicon film is crystallized by laser annealing or the like to form the first semiconductor film 12 made of polysilicon, and then the first semiconductor film 12 is patterned to form the first semiconductor layer 12a.

Subsequently, a silicon oxide film (having a thickness of approximately 100 nm) is formed by plasma CVD, for example, on the substrate surface on which the first semiconductor layer 12a and the like are formed, thus forming the first gate insulating film 13.

Furthermore, after forming the first metal film 14, by forming a molybdenum film (having a thickness of approximately 250 nm) or the like by, for example, sputtering on the substrate surface on which the first gate insulating film 13 is formed, the first metal film 14 is patterned to form the first gate electrode 14a and the like. Here, a line width variation of the first scanning signal line PS formed by patterning the first metal film 14 during manufacturing is larger than a line width variation of the first wiring line 17c formed later by patterning the second semiconductor film 17.

Subsequently, using the first gate electrode 14a as a mask and doping with impurity ions, a part of the first semiconductor layer 12a is caused to be conductive, and the first conductor region 12aa, the second conductor region 12ab, and the first channel region 12ac are formed on the first semiconductor layer 12a.

Thereafter, a silicon nitride film (having a thickness of approximately 100 nm) is formed by, for example, plasma CVD on the substrate surface on which the first semiconductor layer 12a is formed partially conductive, thereby forming the first interlayer insulating film 15.

Furthermore, after forming the second metal film 16, by forming a molybdenum film (having a thickness of approximately 250 nm) or the like by, for example, sputtering on the substrate surface on which the first interlayer insulating film 15 is formed, the second metal film 16 is patterned to form the third wiring line 16c and the like. Here, a line width variation of the third wiring line 16c formed by patterning the second metal film 16 during manufacturing is larger than a line width variation of the first wiring line 17c formed later by patterning the second semiconductor film 17.

Subsequently, after forming the second semiconductor film 17 made of an oxide semiconductor by depositing InGaZnO₄ (having a thickness of about 30 nm) or the like by, for example, sputtering on the substrate surface on which the third wiring line 16c and the like are formed, the second semiconductor layer 17a and the like are formed by patterning the second semiconductor film 17.

Thereafter, a silicon oxide film (having a thickness of approximately 100 nm) is formed by, for example, plasma CVD on the substrate surface on which the second semiconductor layer 17a and the like are formed, thereby forming the second gate insulating film 18.

Furthermore, after forming the third metal film 19, by forming a molybdenum film (having a thickness of approximately 250 nm) or the like by, for example, sputtering on the substrate surface on which the second gate insulating film 18 is formed, the third metal film 19 is patterned to form the second gate electrode 19a and the like.

Subsequently, a silicon oxide film (having a thickness of approximately 300 nm) and a silicon nitride film (having a thickness of approximately 150 nm) are sequentially formed by, for example, plasma CVD on the substrate surface on which the second gate electrode 19a and the like are formed, thereby forming the second interlayer insulating film 20. Note that part of the second semiconductor layer 17a is made conductive by heat treatment after the formation of the second interlayer insulating film 20, so that the third conductor region 17aa (the first wiring line 17c), the fourth conductor region 17ab, and the second channel region 17ac are formed in the second semiconductor layer 17a.

Thereafter, on the substrate surface on which the second interlayer insulating film 20 is formed, the first gate insulating film 13, the first interlayer insulating film 15, the second gate insulating film 18, and the second interlayer insulating film 20 are appropriately patterned to form the contact holes.

Furthermore, after forming the fourth metal film 21 by sequentially forming a titanium film (having a thickness of approximately 50 nm), an aluminum film (having a thickness of approximately 400 nm), a titanium film (having a thickness of approximately 50 nm) and the like by, for example, sputtering on the substrate surface in which the contact holes are formed, the fourth metal film 21 is patterned to form the second wiring line 21c and the like.

Finally, a polyimide-based photosensitive resin film (having a thickness of about 2 μm) is applied to the substrate surface on which the second wiring line 21c and the like are formed, by, for example, spin coating or slit coating, and then the applied film is pre-baked, exposed, developed, and post-baked to form the flattening film 22.

The TFT layer 30a can be formed as described above.

### Organic EL Element Layer Forming Step

The organic EL element layer 40 is formed by forming, using a known method, the first electrode 31, the edge cover 32, the organic EL layer 33, and the second electrode 34 on the flattening film 22 of the TFT layer 30a that has been formed in the TFT layer forming step.

### Sealing Film Forming Step

First, an inorganic insulating film such as a silicon nitride film, a silicon oxide film, or a silicon oxynitride film is formed by plasma CVD on a substrate surface formed with the organic EL element layer 40 formed in the organic EL element layer forming step described above by using a mask to form the first inorganic sealing film 41.

Next, on the substrate surface formed of the first inorganic sealing film 41, a film made of an organic resin material such as an acrylic resin is formed by, for example, using an ink-jet method to form the organic sealing film 42.

Thereafter, an inorganic insulating film such as a silicon nitride film, a silicon oxide film, or a silicon oxynitride film is formed by plasma CVD on the substrate surface formed with the organic sealing film 42 by using a mask to form the second inorganic sealing film 43, thereby forming the sealing film 45.

Finally, after a protective sheet (not illustrated) is applied to the substrate surface formed with the sealing film 45, the glass substrate is peeled off from the lower face of the resin substrate 10 by irradiation with laser light from the glass substrate side of the resin substrate 10, and then a protective sheet (not illustrated) is applied to the lower face of the resin substrate 10, from which the glass substrate has been peeled off. The organic EL display device 100 according to the present embodiment can be manufactured as described above.

As described above, according to the organic EL display device 100 in the present embodiment, the P-type capacitor Cgp electrically connected to the first gate electrode 14a of the drive transistor 9d via the second wiring line 21c includes the first scanning signal line PS formed of the first metal film 14, the first interlayer insulating film 15 provided so as to cover the first scanning signal line PS, the third wiring line 16c formed of the second metal film 16 on the first interlayer insulating film 15, and the first wiring line 17c provided on the third wiring line 16c. Here, since the first wiring line 17c is provided so as to cover the third wiring line 16c at least above the first scanning signal line PS, even when the variation in the width of the third wiring line 16c is large in the P-type capacitor Cgp, the variation in the width of the first wiring line 17c provided so as to cover the third wiring line 16c is small. Therefore, the width of the conductive layer overlapping the first scanning signal line PS with the first interlayer insulating film 15 interposed therebetween becomes the width of the first wiring line 17c with small variation. Thus, it is possible to suppress variations in the electric capacitance of the P-type capacitor Cgp and it is possible to stably raise the voltage of the first gate electrode 14a of the drive transistor 9d. Then, in each of the subpixels P, the voltage of the first gate electrode 14a of the drive transistor 9d is stably raised, thereby suppressing occurrence of display unevenness in the organic EL display device 100.

In addition, according to the organic EL display device 100 in the present embodiment, the third wiring line 16c formed of the second metal film 16 is located below the first wiring line 17c formed of the second semiconductor film 17 made of the oxide semiconductor. Therefore, when the contact hole reaching the first wiring line 17c is formed in the layered film of the second gate insulating film 18 and the second interlayer insulating film 20, even when the contact hole penetrates the first wiring line 17c, it is possible to prevent the contact hole from penetrating the first interlayer insulating film 15. Here, when the contact hole penetrates the first interlayer insulating film 15, the second wiring line 21c and the first scanning signal line PS are short-circuited, making it impossible to form the P-type capacitor Cgp.

Further, according to the organic EL display device 100 according to the present embodiment, since the base coat film 11 made of an inorganic insulating film is provided between the resin substrate 10 and the first semiconductor layer 12a, film peeling of the first semiconductor layer 12a can be suppressed.

### Second Embodiment

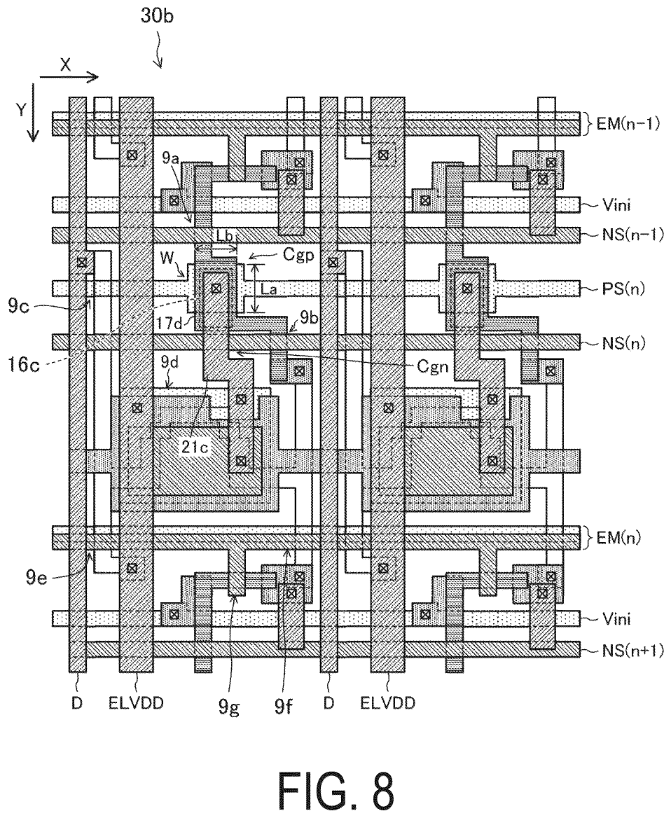

FIG. 8 illustrates a second embodiment of a display device according to the disclosure. Here, FIG. 8 is a plan view of a TFT layer 30b constituting an organic EL display device in the present embodiment and is a view corresponding to FIG. 3 described in the first embodiment. In the following embodiment, parts identical to those in FIG. 1 to FIG. 7 are designated by the same reference signs, and detailed descriptions thereof will be omitted.

In the first embodiment, the organic EL display device 100 including the TFT layer 30a provided with the scanning signal line PS having a constant width is illustrated, while in the present embodiment, the organic EL display device including the TFT layer 30b provided with a scanning signal line PS having a wide portion W will be illustrated.

Similar to the organic EL display device 100 in the first embodiment, the organic EL display device in the present embodiment includes a display region 50 in which a plurality of subpixels P are provided in a matrix shape, and a gate driver 60, an emission driver 70, and a source driver 80 provided in a frame region around the display region 50. Note that a display control circuit 150 electrically connected to the gate driver 60, the emission driver 70, and the source driver 80 is provided outside the organic EL display device in the present embodiment, similar to the display control circuit 150 in the case of the organic EL display device 100 in the first embodiment.

The organic EL display device in the present embodiment includes a resin substrate 10 provided as a base substrate, the TFT layer 30b provided on the resin substrate 10, an organic EL element layer 40 provided as a light-emitting element layer on the TFT layer 30b, and a sealing film 45 provided on the organic EL element layer 40.

Similar to the TFT layer 30a in the first embodiment, the TFT layer 30b includes a base coat film 11 provided on the resin substrate 10, four P-channel type first transistors 9A, three N-channel type second transistors 9B, and one capacitor 9h provided on the base coat film 11 for each subpixel P, and a flattening film 22 provided on the first transistors 9A, the second transistors 9B, and the capacitor 9h. In the TFT layer 30b, as in the TFT layer 30a in the first embodiment, the base coat film 11, a first semiconductor film 12, a first gate insulating film 13, a first metal film 14, a first interlayer insulating film 15, a second metal film 16, a second semiconductor film 17, a second gate insulating film 18, a third metal film 19, a second interlayer insulating film 20, a fourth metal film 21, and the flattening film 22 are sequentially layered on the resin substrate 10.

In the display region 50 of the TFT layer 30b, i pieces of first scanning signal lines PS(1) to PS(i), (i+1) pieces of second scanning signal lines NS(0) to NS(i), i pieces of light emission control lines EM(1) to EM(i), j pieces of data signal lines D(1) to D(j), a high-level power supply line, a low-level power supply line, and an initialization power supply line are provided, in a similar manner to the TFT layer 30a in the first embodiment. Here, as illustrated in FIG. 8, the first scanning signal line PS has a wide portion W, which is wider than adjacent portions, in a portion where a first wiring line 17d covers a third wiring line 16c in each subpixel P.

In the TFT layer 30b, as in the TFT layer 30a in the first embodiment, a write control transistor 9c, a drive transistor 9d, a power supply control transistor 9e, and a light emission control transistor 9f are provided as the four P-channel type first transistors 9A including a first semiconductor layer 12a made of polysilicon, and an initialization transistor 9a, a threshold voltage compensation transistor 9b, and an anode discharge transistor 9g are provided as the three N-channel type second transistors 9B including a second semiconductor layer 17a made of an oxide semiconductor.

In the TFT layer 30b, a third conductor region 17aa of the initialization transistor 9a and a third conductor region 17aa of the threshold voltage compensation transistor 9b are electrically connected via the first wiring line 17d formed of the second semiconductor film 17, as illustrated in FIG. 8.

As illustrated in FIG. 8, the first wiring line 17d is provided so that a portion overlapping the wide portion W extends in a direction orthogonal to the first scanning signal line PS. Here, a length La of a portion of the first wiring line 17d overlapping the wide portion W along the direction orthogonal to the first scanning signal line PS (e.g., about 10 μm) is greater than a length Lb of the portion of the first wiring line 17d overlapping the wide portion W along the direction in which the first scanning signal line PS extends (e.g., about 5 μm). In addition, the first wiring line 17d constitutes a P-type capacitor Cgp in a portion overlapping the first scanning signal line PS(n), as in the first wiring line 17c in the first embodiment. Here, the P-type capacitor Cgp includes the first scanning signal line PS formed of the first metal film 14, the first interlayer insulating film 15 provided so as to cover the first scanning signal line PS, the third wiring line 16c formed of the second metal film 16 on the first interlayer insulating film 15, and the first wiring line 17d provided so as to cover the third wiring line 16c at least above the first scanning signal line PS. It should be noted that the numerical values of the lengths La and Lb described above are merely examples because they vary depending on resolution and configuration of the panel.

In the organic EL display device in the present embodiment, as in the organic EL display device 100 in the first embodiment, in each subpixel P, an organic EL element 35 emits light at a level of luminance corresponding to a drive current, thereby performing image display.

The organic EL display device in the present embodiment can be manufactured by changing the shapes in the patterning of the first metal film 14 and the shapes in the patterning of the second semiconductor film 17 in the TFT layer forming step in the method for manufacturing the organic EL display device 100 in the first embodiment.

As described above, according to the organic EL display device in the present embodiment, the P-type capacitor Cgp electrically connected to the first gate electrode 14a of the drive transistor 9d via the second wiring line 21c includes the first scanning signal line PS formed of the first metal film 14, the first interlayer insulating film 15 provided so as to cover the first scanning signal line PS, the third wiring line 16c formed of the second metal film 16 on the first interlayer insulating film 15, and the first wiring line 17d provided on the third wiring line 16c. Here, since the first wiring line 17d is provided so as to cover the third wiring line 16c at least above the first scanning signal line PS, even when the variation in the width of the third wiring line 16c is large in the P-type capacitor Cgp, the variation in the width of the first wiring line 17d provided so as to cover the third wiring line 16c is small. Therefore, the width of the conductive layer overlapping the first scanning signal line PS with the first interlayer insulating film 15 interposed therebetween becomes the width of the first wiring line 17d with small variation. Thus, it is possible to suppress the variation in the electric capacitance of the P-type capacitor Cgp and it is possible to stably raise the voltage of the first gate electrode 14a of the drive transistor 9d. Then, in each of the subpixels P, the voltage of the first gate electrode 14a of the drive transistor 9d is stably raised, thereby suppressing occurrence of display unevenness in the organic EL display device.

Further, according to the organic EL display device in the present embodiment, the length La of the portion of the first wiring line 17d overlapping the wide portion W along the direction orthogonal to the first scanning signal line PS is greater than the length Lb of the portion of the first wiring line 17d overlapping the wide portion W along the direction in which the first scanning signal line PS extends. Here, the variation in the width direction (X direction) of the first wiring line 17d formed of the second semiconductor film 17 made of the oxide semiconductor tends to be smaller than the variation in the width direction (Y direction) of the first scanning signal line PS formed of the first metal film 14. Therefore, when the variation of the first wiring line 17d in the X direction is ±1 μm, the variation of the first scanning signal line PS in the Y direction is ±2 μm, and the length La is 10 μm and the length Lb is 5 μm based on the relationship that the length La is greater than the length Lb, an area of La×Lb proportional to the electric capacitance of the P-type capacitor Cgp is 32 to 72 μm²(= (8 to 12 μm)×(4 to 6 μm)). Conversely, when the length La is 5 μm and the length Lb is 10 μm based on the relationship of that the length La is smaller than the length Lb, the area of La×Lb proportional to the electric capacitance of the P-type capacitor Cgp is 27 to 77 μm²(=(3 to 7 μm)×(9 to 11 μm)). Therefore, when the length La is greater than the length Lb, variation in the electric capacitance of the P-type capacitor Cgp can be suppressed.

In addition, according to the organic EL display device in the present embodiment, the third wiring line 16c formed of the second metal film 16 is located below the first wiring line 17d formed of the second semiconductor film 17 made of the oxide semiconductor. Therefore, when the contact hole reaching the first wiring line 17d is formed in the layered film of the second gate insulating film 18 and the second interlayer insulating film 20, even when the contact hole penetrates the first wiring line 17d, it is possible to prevent the contact hole from penetrating the first interlayer insulating film 15. Here, when the contact hole penetrates the first interlayer insulating film 15, the second wiring line 21c and the first scanning signal line PS are short-circuited, making it impossible to form the P-type capacitor Cgp.

Further, according to the organic EL display device in the present embodiment, since the base coat film 11 formed of the inorganic insulating film is provided between the resin substrate 10 and the first semiconductor layer 12a, film peeling of the first semiconductor layer 12a can be suppressed.

### Other Embodiments

Although the organic EL layer having a five-layer structure including the hole injection layer, the hole transport layer, the light-emitting layer, the electron transport layer, and the electron injection layer has been exemplified in each of the embodiments described above, the organic EL layer may have a three-layer structure including a hole injection-cum-transport layer, a light-emitting layer, and an electron transport-cum-injection layer, for example.

In each of the embodiments described above, the organic EL display device including the first electrode as an anode electrode and the second electrode as a cathode electrode is exemplified. The disclosure is also applicable to an organic EL display device in which the layered structure of the organic EL layer is reversed with the first electrode being a cathode electrode and the second electrode being an anode electrode.

In each of the embodiments described above, the organic EL display device is exemplified as a display device. The disclosure can also be applied to a display device including a plurality of light-emitting elements driven by a current, for example, to a display device including quantum dot light-emitting diodes (QLEDs), which are a light-emitting element using a quantum dot-containing layer.

### INDUSTRIAL APPLICABILITY

As described above, the disclosure is useful for a flexible display device.

### REFERENCE SIGNS LIST

H Contact hole
NS Second scanning signal line
NG Node G
P Subpixel
PS First scanning signal line
W Wide portion
9A First transistor
9B Second transistor
9C Third transistor
9a Initialization transistor (second transistor)
9b Threshold voltage compensation transistor (second transistor)
9c Write control transistor (first transistor)
9d Drive transistor (first transistor)
9e Power supply control transistor (first transistor)
9f Light emission control transistor (first transistor)
9g Anode discharge transistor (second transistor)
10 Resin substrate (base substrate)
11 Base coat film
12 First semiconductor film
12a First semiconductor layer
12aa First conductor region
12ab Second conductor region
12ac First channel region
13 First gate insulating film (first inorganic insulating film)
14 First metal film
14a First gate electrode
15 First interlayer insulating film (second inorganic insulating film)
16 Second metal film
16c Third wiring line
17 Second semiconductor film
17a Second semiconductor layer
17aa Third conductor region
17ab Fourth conductor region
17ac Second channel region
17c, 17d First wiring line
18 Second gate insulating film (third inorganic insulating film)
19 Third metal film
19a Second gate electrode
20 Second interlayer insulating film (fourth inorganic insulating film)
21 Fourth metal film
21c Second wiring line
30a, 30b TFT layer (thin film transistor layer)
35 Organic EL element (organic electroluminescence element, light-emitting element)
40 Organic EL element layer (light-emitting element layer)
45 Sealing film
50 Display region
100 Organic EL display device

1. A display device comprising:
a base substrate; and
a thin film transistor layer provided on the base substrate, the thin film transistor layer being formed by sequentially layering a first semiconductor film made of polysilicon, a first inorganic insulating film, a first metal film, a second inorganic insulating film, a second metal film, a second semiconductor film made of an oxide semiconductor, a third inorganic insulating film, a third metal film, a fourth inorganic insulating film, and a fourth metal film,
wherein subpixels constitute a display region,
the thin film transistor layer includes, for each of the subpixels,
first transistors, each of the first transistors including
a first semiconductor layer formed of the first semiconductor film, in which a first conductor region and a second conductor region are located apart from each other and a first channel region is located between the first conductor region and the second conductor region, and
a first gate electrode formed of the first metal film and overlapping the first channel region, and
second transistors, each of the second transistors including
a second semiconductor layer formed of the second semiconductor film, in which a third conductor region and a fourth conductor region are located apart from each other and a second channel region is located between the third conductor region and the fourth conductor region, and
a second gate electrode formed of the third metal film and overlapping the second channel region,
as the first transistors, a write control transistor, a drive transistor, a power supply control transistor, and a light emission control transistor are provided,
as the second transistors, an initialization transistor and a threshold voltage compensation transistor are provided,
the third conductor region in the initialization transistor and the third conductor region in the threshold voltage compensation transistor are electrically connected via a first wiring line formed of the second semiconductor film,
the first gate electrode of the drive transistor is electrically connected to the first wiring line via a second wiring line formed of the fourth metal film,
in each of the subpixels, a first scanning signal line electrically connected to the first gate electrode of the write control transistor and formed of the first metal film, a second scanning signal line electrically connected to the second gate electrode of the threshold voltage compensation transistor on one side of the first scanning signal line and formed of the third metal film, and another second scanning signal line electrically connected to the second gate electrode of the initialization transistor on another side of the first scanning signal line and formed of the third metal film extend parallel to each other,
a third wiring line formed of the second metal film is electrically connected to the second wiring line, and
the first wiring line covers the third wiring line at least above the first scanning signal line.

2. The display device according to claim 1,
wherein a film thickness of the second semiconductor film is smaller than a film thickness of the second metal film.

3. The display device according to claim 1,
wherein the second wiring line intersects the second scanning signal line provided on the one side of the first scanning signal line.

4. The display device according to claim 1,
wherein the first wiring line is provided directly on the third wiring line.

5. The display device according to claim 1,
wherein the second wiring line is electrically connected to the first wiring line via a contact hole formed in the third inorganic insulating film and the fourth inorganic insulating film, and
the contact hole is provided in a region overlapping the third wiring line in a plan view.

6. The display device according to claim 5,
wherein the contact hole is provided in a region where the first wiring line and the third wiring line overlap in a plan view.

7. The display device according to claim 6,
wherein the contact hole penetrates the first wiring line.

8. The display device according to claim 5,
wherein the contact hole is provided above the first scanning signal line.

9. The display device according to claim 1,
wherein the second metal film is composed of a molybdenum film.

10. The display device according to claim 1,
wherein as one of the second transistors, an anode discharge transistor is provided.

11. The display device according to claim 1,
wherein the first scanning signal line includes a wide portion wider than an adjacent portion in a portion where the first wiring line covers the third wiring line,
a portion of the first wiring line overlapping the wide portion extends in a direction orthogonal to the first scanning signal line, and
a length of the portion of the first wiring line overlapping the wide portion along the direction orthogonal to the first scanning signal line is greater than a length of the portion of the first wiring line overlapping the wide portion along a direction in which the first scanning signal line extends.

12. The display device according to claim 11,
wherein the first metal film is composed of a molybdenum film.

13. The display device according to claim 1,
wherein the base substrate is a resin substrate,
a base coat film is provided on the resin substrate, and
the first semiconductor film is provided on the base coat film.

14. The display device according to claim 1, comprising:
a light-emitting element layer provided on the thin film transistor layer and including a plurality of light-emitting elements being arrayed; and
a sealing film provided on the light-emitting element layer.

15. The display device according to claim 14,
wherein each of the plurality of light-emitting elements is an organic electroluminescence element.
